(19) United States
(12) Patent Application Publication
(10) Pub. No.: US 2021/0028196 A1
(43) Pub. Date: Jan. 28, 2021

(54) ARRAY SUBSTRATE, MANUFACTURING METHOD THEREOF, DISPLAY PANEL AND DISPLAY DEVICE

(71) Applicants: Hefei Xinsheng Optoelectronics Technology Co., Ltd., Hefei (CN); BOE Technology Group Co., Ltd., Beijing (CN)

(72) Inventor: Ming WANG, Beijing (CN)

(73) Assignees: Hefei Xinsheng Optoelectronics Technology Co., Ltd.; BOE Technology Group Co., Ltd.

(21) Appl. No.: 16/858,879

(22) Filed: Apr. 27, 2020

(30) Foreign Application Priority Data
Jul. 25, 2019 (CN) 201910677829.8

(51) Int. Cl. H01L 27/12

(52) U.S. Cl. CPC H01L 27/1244; H01L 27/3262; H01L 27/1259; H01L 27/1248

(57) ABSTRACT

The present disclosure provides an array substrate, a manufacturing method thereof, a display panel and a display device. Where the array substrate includes a base substrate; source and drain electrode metal layers, arranged on the base substrate; and an inorganic insulating layer, arranged on the source and drain electrode metal layers; where, the array substrate includes a display area and a peripheral area surrounding the display area; the inorganic insulating layer has a first thickness in the display area and a second thickness in the peripheral area, and the first thickness is smaller than the second thickness.

The present application claims the priority from Chinese Patent Application No. 201910677829.8, filed with the Chinese Patent Office on Jul. 25, 2019, and entitled “ARRAY SUBSTRATE, MANUFACTURING METHOD THEREOF, DISPLAY PANEL AND DISPLAY DEVICE”, which is hereby incorporated by reference in its entirety.

### FIELD

The present application relates to the technical field of semiconductors, in particular to an array substrate, a manufacturing method thereof, a display panel and a display device.

### BACKGROUND

As shown in FIG. 1, in an array substrate of a display device, an insulating layer 101 is commonly arranged on source and drain electrode metal layers so that the source and drain electrode metal layers 102 can be protected. Since the source and drain electrode metal layers 102 are commonly of double-layer metal layer structures such as a double-layer copper (Cu) structure, if silicon oxide (SIO) with a high-density structure is adopted in the insulating layer 101, the source and drain electrode metal layers 102 can be oxidized. Thus, a low-density structure is adopted in the current insulating layer 101. But, the density of the insulating layer 101 is low, wiring areas (such as an area A and an area B shown in FIG. 1) on the periphery of a display panel are corroded due to a later etch technology, consequently, the phenomenon similar to the point discharge happens.

### SUMMARY

The present application provides an array substrate, a manufacturing method thereof, a display panel and a display device. In a first aspect, an array substrate provided in one embodiment of the present application includes:

a base substrate;

source and drain electrode metal layers, arranged on the base substrate; and

an inorganic insulating layer, arranged on the source and drain electrode metal layers;

where, the array substrate includes a display area and a peripheral area surrounding the display area, the inorganic insulating layer has a first thickness in the display area and a second thickness in the peripheral area, and the first thickness is smaller than the second thickness.

In a possible implementation, a difference value between the second thickness and the first thickness is larger than or equal to ⅓ of the first thickness and smaller than ⅔ of the first thickness.

In a possible implementation, the first thickness is in a range of [300 nm, 400 nm].

In a possible implementation, the array substrate further includes:

an organic insulating layer, arranged on the inorganic insulating layer in the display area.

In a possible implementation, a thickness of the organic insulating layer is larger than the difference value between the second thickness and the first thickness.

In a possible implementation, the array substrate further includes:

an electrode layer, where the electrode layer is electrically connected with the source and drain electrode metal layers through via holes penetrating the inorganic insulating layer and the organic insulating layer.

In a possible implementation, the array substrate further includes:

an active layer, a grid insulating layer and a grid layer;

where the active layer, the grid insulating layer and the grid layer are arranged between the base substrate and the source and drain electrode metal layers, the active layer is close to the base substrate, and the grid layer is close to the source and drain electrode metal layers.

In a second aspect, an embodiment of the present application provides an organic light emitting diode (OLED) display panel, and the OLED display panel includes the array substrate according to the first aspect.

In a third aspect, an embodiment of the present application provides a display device, and the display device includes the OLED display panel according to the second aspect.

In a fourth aspect, an embodiment of the present application provides a method for manufacturing an array substrate, where the array substrate includes a display area and a peripheral area surrounding the display area, and the method includes:

manufacturing source and drain electrode metal layers on a base substrate; and

depositing an inorganic insulating layer on the source and drain electrode metal layers and thinning the inorganic insulating layer, where after thinning the inorganic insulating layer, the inorganic insulating layer has a first thickness in the display area and a second thickness in the peripheral area, and the first thickness is smaller than the second thickness.

In a possible implementation, the method further includes:

depositing an organic insulating layer on the inorganic insulating layer in the display area;

patterning the organic insulating layer to form a first via hole;

etching the inorganic insulating layer to form a second via hole; and

forming an electrode layer on the organic insulating layer, where the electrode layer is electrically connected with the source and drain electrode metal layers through the first via hole and the second via hole.

In a possible implementation, before manufacturing the source and drain electrode metal layers on the base substrate, the method further includes:

forming an active layer, a grid insulating layer and a grid layer on the base substrate, sequentially.

### BRIEF DESCRIPTION OF THE DRAWINGS

FIG. 1 is a schematic structural diagram of an array substrate in the prior art.

FIG. 2 is a schematic diagram of happening data gate short (DGS) in the structure shown in FIG. 1.

FIG. 3 is a schematic structural diagram of an array substrate provided in an embodiment of the present application.

FIG. 4 is another schematic structural diagram of an array substrate provided in an embodiment of the present application.

FIG. 5 is another schematic structural diagram of an array substrate provided in an embodiment of the present application.

FIG. 6 is a schematic diagram of a film structure in the display area 0 of an array substrate provided in an embodiment of the present application.

FIG. 7 is a process schematic diagram of a method for manufacturing an array substrate provided in an embodiment of the present application.

FIG. 8(a)-FIG. 8(f) is a schematic structural diagram involved in an array substrate manufacturing process provided in an embodiment of the present application.

FIG. 9(a) is a corrosion result schematic diagram of a peripheral area of an array substrate in the prior art.

FIG. 9(b) is a corrosion result schematic diagram of a peripheral area of an array substrate provided in an embodiment of the present application.

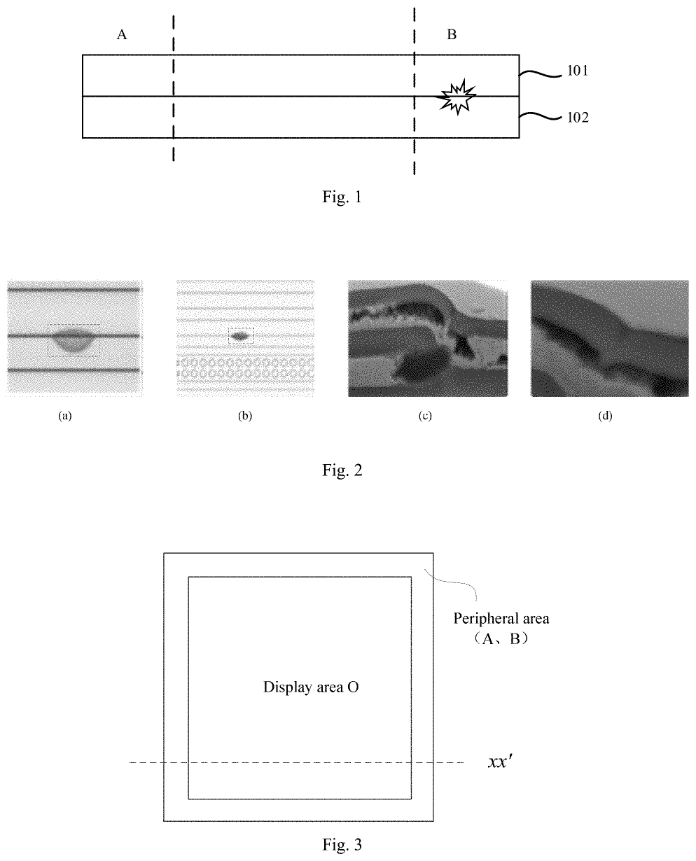

### DETAILED DESCRIPTION OF THE EMBODIMENTS

To make the object, the technical scheme and advantages of embodiments of the present disclosure clearer, the technical schemes of the embodiments of the present disclosure are clearly and completely described with reference to the accompanying drawings of the embodiments of the present disclosure. Obviously, the described embodiments are only part but not all of the embodiments of the present disclosure. Based on the described embodiments of the present disclosure, all other embodiments obtained by ordinary technical personnel in the art on the premise that creative labor is not needed fall within the protection scope of the present disclosure.

An inorganic insulating layer on source and drain electrode metal layers of a current array substrate is commonly of a double-layer metal layer structure, and in order to avoid oxidization of the source and drain electrode metal layers by the inorganic insulating layer as much as possible, an inorganic insulating film with low density is commonly adopted. But if the density of the inorganic insulating film is low, and there is no a resin layer protecting the inorganic insulating film in the peripheral area, so that the inorganic insulating film can be corroded due to implementing of an etch technology on the peripheral area of the array substrate later, and DGS happens to the peripheral area. With regard to other films, such as a gate layer, since the gate layer is generally located below the source and drain electrode metal layers, thus the gate layer is not likely to be corroded. As shown in FIG. 2, DGS is likely to happen to the source and drain electrode metal layers in the peripheral area, and the product yield is low. The dotted box as shown in FIG. 2(b) is a position where the source and drain electrode metal layers are corroded, and FIG. 2(a) is an enlarged view of the dotted box as shown in FIG. 2(b). Referring to FIG. 2(c), after performing an analysis of focused ion beam on the corrosion area, it's found that the source and drain electrode metal layers are corroded. FIG. 2(d) is an enlarged view of the inorganic insulating film above the source and drain electrode metal layers, and it can be seen that the liquid permeates due to cracks.

For that reason, an embodiment of the present application provides an array substrate, thus when an etching technology is conducted on the peripheral area of the array substrate later, the corrosion degree of the peripheral area due to the etch technology is reduced, accordingly, the probability of the DGS is reduced, and the product yield is increased.

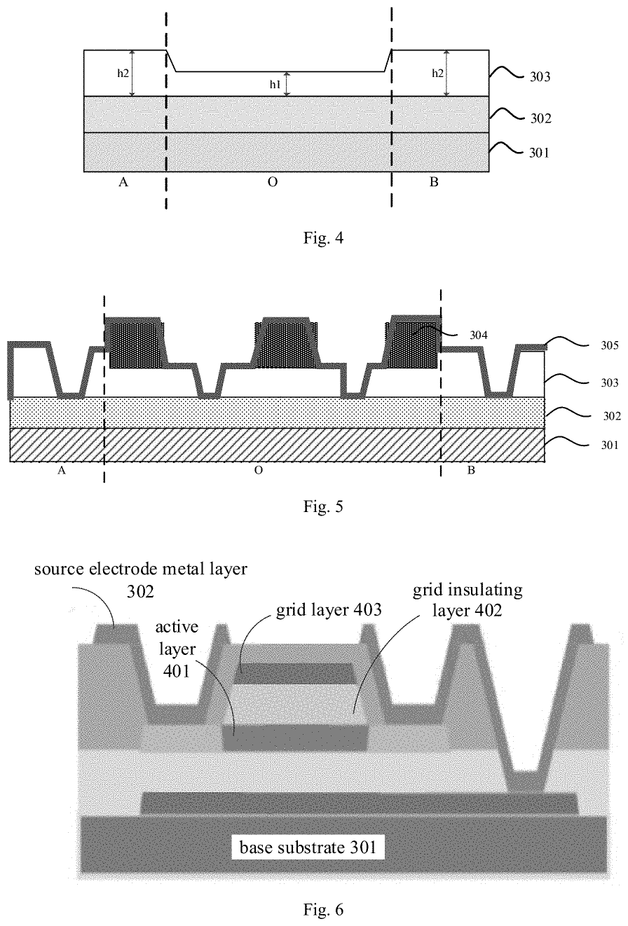

Specifically, as shown in FIG. 3, an embodiment of the present application provides an array substrate. FIG. 3 is a top view of the array substrate, and along the cutting line xx′ and a direction perpendicular to the surface of the array substrate, the array substrate is cut to obtain to side views of a part of the film structure of the array substrate as shown in FIGS. 4-6. The array substrate includes a base substrate 301, source and drain electrode metal layers 302 located on the base substrate 301 and an inorganic insulating layer 303 located on the source and drain electrode metal layers 302; where, the array substrate includes a display area O and a peripheral area (A, B) surrounding the display area O, the inorganic insulating layer 303 has a first thickness h1 in the display area O and a second thickness h2 in the peripheral area (A, B), and the first thickness h1 is smaller than the second thickness h2. Where, the display area O is a pixel area, and the peripheral area (A, B) is a peripheral wiring area surrounding the display area O.

Since the thickness of the inorganic insulating layer 303 of the peripheral area (A, B) of the array substrate is larger than the thickness of the inorganic insulating layer 303 of the display area O, silicon dioxide with a low density structure is adopted in the inorganic insulating layer 303, so that oxidization of the source and drain electrode metal layers 302 can be reduced, the corrosion degree of the peripheral area (A, B) due to the etch technology can also be reduced, and accordingly the probability of the DGS is reduced.

In an implementation, a difference value between the second thickness and the first thickness is larger than or equal to ⅓ of the first thickness and smaller than ⅔ of the first thickness. If the first thickness is too large, then the capacitance of the array substrate is low, and displaying of the display area O of the array substrate is poor; and if the first thickness is too small, then the source and drain electrode metal layers 302 below the inorganic insulating layer 303 cannot be well protected, thus, in the embodiments of the present application, the first thickness may be in a range of [300 nm, 400 nm], the source and drain electrode metal layers 302 can be well protected, the large capacitance of the array substrate is also guaranteed, and good displaying of the display area O is guaranteed. Relatively, the second thickness may be larger than the first thickness by 100 nm-200 nm, for example, the second thickness may be in a range of [400 nm, 600 nm].

Furthermore, as shown in FIG. 5, in an embodiment of the present application, an organic insulating layer 304 is provided on the inorganic insulating layer 303 in the display area O, so that a film layer of the display area O can be protected. For example, the material of the organic insulating layer 304 may be resin. In an implementation, the thickness of the organic insulating layer 304 is larger than the difference value between the second thickness and the first thickness.

In addition, an array substrate provided in an embodiment of the present application is further provided with an electrode layer 305 electrically connected with the source and drain electrode metal layers 302. The electrode layer 305 may serves as an anode of the light emitting material. Exemplary, the material of the electrode layer 305 may be indium tin oxide (ITO). The inorganic insulating layer 303 may be provided with a via hole, meanwhile, the organic insulating layer 304 is also provided with a via hole, and the electrode layer 305 can penetrate through the via holes of the organic insulating layer 304 and the inorganic insulating layer 303 sequentially and is electrically connected with the source and drain electrode metal layers 302.

In an implementation, the array substrate may further include some film layers, as shown in FIG. 6, in the display area O, such as an active layer 401, a grid insulating layer 402 and a grid layer 403 which are located between the base substrate 301 and the source and drain electrode metal layers 302; where the active layer 401 is close to the base substrate 301, and the grid layer 403 is close to the source and drain electrode metal layers 302.

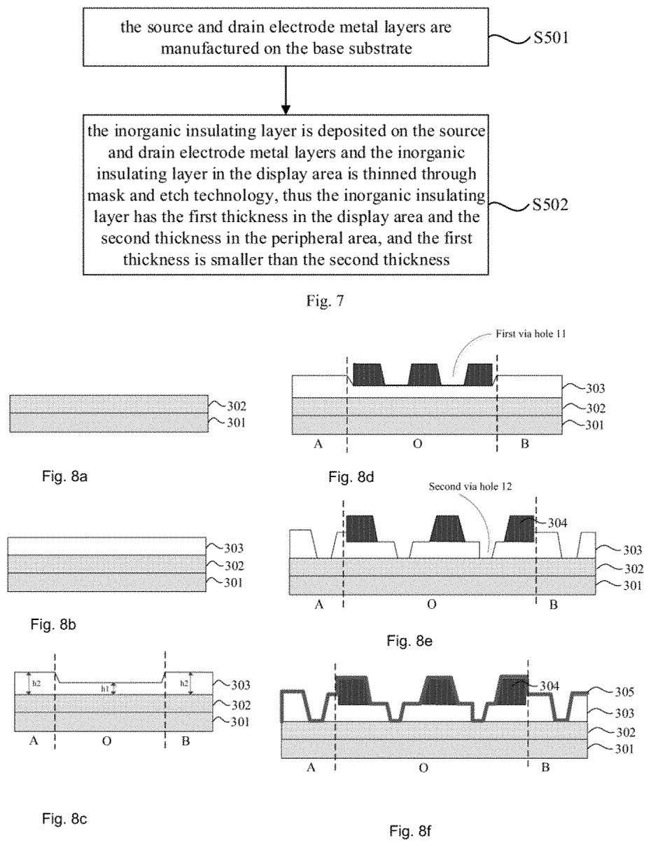

As shown in FIG. 7, on the basis of the same invention concept, an embodiment of the present application further provides a method for manufacturing the above array substrate. The method for manufacturing the array substrate provided in the embodiment of the present application is introduced below with reference to FIG. 8, and the method includes following specific processes:

S501, the source and drain electrode metal layers 302 are manufactured on the base substrate 301.

Where, a metal layer such as a copper layer may be deposited on the base substrate 301, the metal layer is etched to form the source and drain electrode metal layers 302, and a structure shown in FIG. 8(a) is obtained. In some embodiments, before the metal layer is deposited on the base substrate 301, the active layer 401, the grid insulating layer 402 and the grid layer 403 may be sequentially formed on the base substrate 301.

S502, the inorganic insulating layer 303 is deposited on the source and drain electrode metal layers 302 and the inorganic insulating layer 303 in the display area O is thinned through mask and etch technology, thus the inorganic insulating layer 303 has the first thickness h1 in the display area O and the second thickness h2 in the peripheral area (A, B), and the first thickness h1 is smaller than the second thickness h2. The first thickness h1 and the second thickness h2 respectively represent the thickness (also called height) of the inorganic insulating layer 303 deposited in the display area O and the peripheral area (A, B), in the direction perpendicular to the base substrate 301. Where, the specific process flow of thinning includes: 1) coating the photoresist on the inorganic insulating layer 303; 2) only exposing the photoresist in the display area O; 3) performing developing, so that the photoresist in the display area O disappears; 4) etching the inorganic insulating layer 303 in the display area O, where the inorganic insulating layer 303 in the peripheral area (A, B) is not damaged due to the protection of the photoresist; 5) removing the photoresist in the peripheral area (A, B).

Where, the inorganic insulating layer 303 is deposited on the source and drain electrode metal layers 302, for example, a layer of SIO is deposited, and a structure shown in FIG. 8(b) is obtained. Then, the inorganic insulating layer 303 in the display area O is thinned, the thickness of the inorganic insulating layer 303 of the peripheral area (A, B) does not change, accordingly, the inorganic insulating layer 303 may have the first thickness in the display area O and the second thickness in the peripheral area (A, B), the first thickness is smaller than the second thickness, and a structure shown in FIG. 8(c) is obtained.

The organic insulating layer 304 is deposited on the inorganic insulating layer 303 in the display area O of the structure shown in FIG. 8(c), for example, a layer of Resin is deposited, patterning treatment is conducted on the organic insulating layer 304, at least one first via hole 11 is formed, and a structure shown in FIG. 8(d) is obtained. Then, below the first via hole, etching treatment is conducted on the inorganic insulating layer 303, at least one second via hole 12 is formed, where the first via hole 11 and the second via hole 12 are partially overlapped, and a structure shown in FIG. 8(e) is obtained.

The electrode layer 305 such as an ITO film layer is formed on the side, away from the base substrate 301, of the structure shown in FIG. 8(e), the electrode layer 305 may be electrically connected with the source and drain electrode metal layers 302 through the first via hole 11 and the second via hole 12, and a structure shown in FIG. 8(f) is obtained.

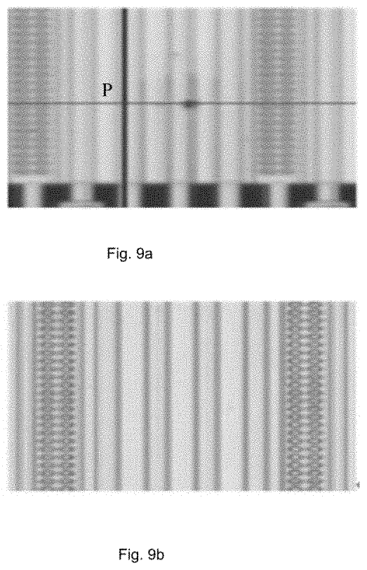

Compared with a method for manufacturing an array substrate in the prior art, that is, the thickness of an inorganic insulating layer 303 of a display area O and the thickness of an inorganic insulating layer 303 of a peripheral area (A, B) are consistent, and the corrosion result for the peripheral areas (A, B) through a later etch technology is shown in FIG. 9(a). According to the array substrate provided in the embodiment of the present application, the thickness of the inorganic insulating layer 303 of the display area O is smaller than that of the inorganic insulating layer 303 of the peripheral area (A, B), and the corrosion result for the peripheral area (A, B) through the later etch technology is shown in FIG. 9(b).

It can be seen from comparison of FIG. 9(a) and FIG. 9(b) that a corroded point (an intersecting point P of two lines in FIG. 9(a)) exists in an inorganic insulating layer as shown in FIG. 9(a), and therefore DGS is likely to happen to a grid line and a data line (two lines in FIG. 9(a)) corresponding to the point P; of course, multiple corroded points may exist in an inorganic insulating layer in the prior art, for example, three corroded points exist in an inorganic insulating layer, and correspondingly, DGS is likely to happen to the grid lines and the data lines corresponding to the three corroded points respectively. However, there is no corroded point in an inorganic insulating layer as shown in FIG. 9(b).

On the basis of the same invention concept, an embodiment of the present application further provides an OLED display panel, and the OLED display panel includes any array substrate mentioned above.

On the basis of the same invention concept, an embodiment of the present application further provides a display device, and the display device includes the above OLED display panel.

In conclusion, the embodiments of the present application provide the array substrate, the manufacturing method thereof, the display panel and the display device, where the thickness of the inorganic insulating layer of the peripheral area of the array substrate is larger than the thickness of the inorganic insulating layer of the display area, thus, even when the density of the inorganic insulating layer is low, the etch technology is conducted on the peripheral area later, the corrosion degree of the peripheral area due to the etch technology can be reduced as much as possible, accordingly, the probability of DGS is reduced, and the product yield is increased.

Obviously, technical personnel in the art can make various modifications and transformations on the present application without separating from the spirit and the scope of the present application. Accordingly, if the modifications and transformations of the present application fall within the scope of the claims of the present application and equivalent technologies thereof, the present application also intends to include the modifications and transformations.

What is claimed is:

1. An array substrate, comprising:
a base substrate;
source and drain electrode metal layers, arranged on the base substrate; and
an inorganic insulating layer, arranged on the source and drain electrode metal layers;
wherein,
the array substrate comprises a display area and a peripheral area surrounding the display area;
the inorganic insulating layer has a first thickness in the display area and a second thickness in the peripheral area; and
the first thickness is smaller than the second thickness.

2. The array substrate according to claim 1, wherein a difference value between the second thickness and the first thickness is larger than or equal to ⅓ of the first thickness and smaller than ⅔ of the first thickness.

3. The array substrate according to claim 1, wherein the first thickness is in a range of [300 nm, 400 nm].

4. The array substrate according to claim 1, further comprising:
an organic insulating layer, arranged on the inorganic insulating layer in the display area.

5. The array substrate according to claim 4, wherein a thickness of the organic insulating layer is larger than the difference value between the second thickness and the first thickness.

6. The array substrate according to claim 4, further comprising:
an electrode layer, wherein the electrode layer is electrically connected with the source and drain electrode metal layers through via holes penetrating the inorganic insulating layer and the organic insulating layer.

7. The array substrate according to claim 6, further comprising:
an active layer, a grid insulating layer and a grid layer;
wherein the active layer, the grid insulating layer and the grid layer are arranged between the base substrate and the source and drain electrode metal layers, the active layer is close to the base substrate, and the grid layer is close to the source and drain electrode metal layers.

8. An organic light emitting diode (OLED) display panel, comprising the array substrate according to claim 1.

9. A display device, comprising the OLED display panel according to claim 8.

10. A method for manufacturing an array substrate, wherein the array substrate comprises a display area and a peripheral area surrounding the display area, and the method comprises:
manufacturing source and drain electrode metal layers on a base substrate; and
depositing an inorganic insulating layer on the source and drain electrode metal layers; and
thinning the inorganic insulating layer, wherein after thinning the inorganic insulating layer, the inorganic insulating layer has a first thickness in the display area and a second thickness in the peripheral area, and the first thickness is smaller than the second thickness.

11. The method according to claim 10, further comprising:
depositing an organic insulating layer on the inorganic insulating layer in the display area;
patterning the organic insulating layer to form a first via hole;
etching the inorganic insulating layer to form a second via hole; and
forming an electrode layer on the organic insulating layer, wherein the electrode layer is electrically connected with the source and drain electrode metal layers through the first via hole and the second via hole.

12. The method according to claim 10, wherein before manufacturing the source and drain electrode metal layers on the base substrate, the method further comprises:
forming an active layer, a grid insulating layer and a grid layer on the base substrate, sequentially.
